(19) United States
(12) Patent Application Publication
(10) Pub. No.: US 2013/0208546 A1
(43) Pub. Date: Aug. 15, 2013

(54) LATENCY CONTROL CIRCUIT AND SEMICONDUCTOR MEMORY DEVICE COMPRISING SAME

(71) Applicant: SAMSUNG ELECTRONICS CO., LTD., SUWON-SI (KR)

(72) Inventors: SI-HONG KIM, YONGIN-SI (KR); SEUNG-JUN BAE, HWASEONG-SI (KR); HYE-RAN KIM, HWASEONG-SI (KR); HO-SEOK SEOL, SUSEONG-GU (KR)

(73) Assignee: SAMSUNG ELECTRONICS CO., LTD., SUWON-SI (KR)

(21) Appl. No.: 13/743,412

(22) Filed: Jan. 17, 2013

(30) Foreign Application Priority Data
Feb. 10, 2012 (KR) 10-2012-0013948

(51) Int. Cl. G11C 8/18; G11C 7/10

(52) U.S. Cl. CPC G11C 8/18; G11C 7/10
USPC 365/189.02; 365/189.05; 365/193

(57) ABSTRACT

A latency control circuit is configured to delay a read information signal in response to a CAS latency signal and an internal clock signal to generate a delayed read information signal, and is further configured to generate a latency control signal based on the delayed read information signal in response to a plurality of sampling control signals and a plurality of transfer control signals.

### CROSS-REFERENCE TO RELATED APPLICATIONS

This application claims priority under 35 U.S.C. §119 to Korean Patent Application No. 10-2012-0013948 filed on Feb. 10, 2012, the subject matter of which is hereby incorporated by reference in its entirety.

### BACKGROUND OF THE INVENTION

The inventive concept relates generally to electronic memory technologies. More particularly, the inventive concept relates to semiconductor memory devices and latency control circuits for the semiconductor memory devices.

Synchronous memory devices are typically configured to synchronize operations with a clock signal generated by an external device. This synchronization can be used, for instance, to synchronize input and output operations with a system bus or memory controller. In light of this synchronization, a memory controller may be designed to anticipate or control a clock cycle where valid data should be output after a read command is applied to a synchronous memory device.

Synchronous semiconductor devices typically required to internally read data in response to the read command, and output data after a predetermined number of clock cycles, which generally corresponds to a column address strobe (CAS) latency. In general, the CAS latency can be controlled by a latency control circuit.

### SUMMARY OF THE INVENTION

In one embodiment of the inventive concept, a latency control circuit comprises a sampling clock signal generating circuit configured to generate a plurality of sampling clock signals having different phases from each other based on an internal clock signal, a multiplexer configured to multiplex the sampling clock signals in response to a CAS latency signal to generate a plurality of sampling control signals, a transfer control signal generating circuit configured to generate a plurality of transfer control signals having different phases from each other based on an output clock signal, and a latency control signal generating circuit configured to delay a read information signal in response to the CAS latency signal and the internal clock signal to generate a delayed read information signal, and further configured to generate a latency control signal based on the delayed read information signal in response to the sampling control signals and the transfer control signals.

In another embodiment of the inventive concept, a semiconductor memory device comprises a memory cell array, a latency control circuit configured to delay a read information signal in response to a CAS latency signal and an internal clock signal to generate a delayed read information signal, and further configured to generate a latency control signal based on the delayed read information signal in response to a plurality of sampling control signals and a plurality of transfer control signals, and an output buffer configured to receive data from the memory cell array and output the data received from the memory cell array in response to the latency control signal.

In another embodiment of the inventive concept, a latency control circuit is configured to delay a read information signal in response to a CAS latency signal and an internal clock signal to generate a delayed read information signal, and is further configured to generate a latency control signal based on the delayed read information signal in response to a plurality of sampling control signals and a plurality of transfer control signals.

These and other embodiments of the inventive concept can potentially allow latency control circuits and semiconductor devices to be implemented with relatively small size, improved performance, and high latency values.

### BRIEF DESCRIPTION OF THE DRAWINGS

The drawings illustrate selected embodiments of the inventive concept. In the drawings, like reference numbers indicate like features.

FIG. 1 is a block diagram of a latency control circuit according to an embodiment of the inventive concept.

FIG. 2 is a circuit diagram of a sampling clock signal generating circuit in the latency control circuit of FIG. 1 according to an embodiment of the inventive concept.

FIG. 3 is a circuit diagram of a delay circuit in the latency control circuit of FIG. 1 according to an embodiment of the inventive concept.

FIG. 4 is a circuit diagram of a latch circuit in the latency control circuit of FIG. 1 according to an embodiment of the inventive concept.

FIG. 5 is a circuit diagram of a transfer control signal generating circuit in the latency control circuit of FIG. 1 according to an embodiment of the inventive concept.

FIG. 6 is a timing diagram illustrating an operation of the latency control circuit of FIG. 1 according to an embodiment of the inventive concept.

FIG. 7 is a block diagram of a latency control circuit according to another embodiment of the inventive concept.

FIG. 8 is a circuit diagram of a delay circuit in the latency control circuit of FIG. 7 according to an embodiment of the inventive concept.

FIG. 9 is a block diagram of a semiconductor memory device comprising a latency control circuit according to an embodiment of the inventive concept.

FIG. 10 is a block diagram of a memory system comprising a semiconductor memory device according to an embodiment of the inventive concept.

FIG. 11 is a diagram of a stacked semiconductor device comprising a semiconductor memory device comprising an internal voltage generating circuit according to an embodiment of the inventive concept.

FIG. 12 is a block diagram of a memory system comprising a semiconductor memory device according to an embodiment of the inventive concept.

FIG. 13 is a block diagram of an electronic system comprising a semiconductor memory device comprising an internal voltage generating circuit according to an embodiment of the inventive concept.

### DETAILED DESCRIPTION

Embodiments of the inventive concept are described below with reference to the accompanying drawings. These embodiments are presented as teaching examples and should not be construed to limit the scope of the inventive concept.

In the description that follows, where a feature is referred to as being “on,” “connected to” or “coupled to” another feature, it can be directly on, connected or coupled to the other feature or intervening features may be present. In contrast, where a feature is referred to as being “directly on,” “directly connected to” or “directly coupled to” another feature, there are no intervening features present. As used herein, the term “and/or” indicates any and all combinations of one or more of the associated listed items.

The terms first, second, third, etc. may be used herein to describe various features, but the described features should not be limited by these terms. Rather, these terms are used merely to distinguish between different features. Accordingly, a first feature discussed below could be termed a second feature and vice versa without departing from the relevant teachings.

Spatially relative terms, such as “beneath,” “below,” “lower,” “above,” “upper” and the like, may be used herein for ease of description to describe one feature's relationship to another feature as illustrated in the drawings. The spatially relative terms are intended to encompass different orientations of a device in use or operation in addition to the orientation depicted in the drawings. For example, if a device in the drawings is turned over, features described as “below” or “beneath” other features would then be oriented “above” the other features. Thus, the term “below” can encompass both an orientation of above and below. The device may be otherwise oriented (rotated 90 degrees or at other orientations) and the spatially relative descriptors interpreted accordingly.

The terminology used herein is for the purpose of describing particular embodiments only and is not intended to be limiting of the inventive concept. As used herein, the singular forms “a,” “an” and “the” are intended to encompass the plural forms as well, unless the context clearly indicates otherwise. The terms “comprises” and/or “comprising,” where used in this specification, indicate the presence of stated features but do not preclude the presence or addition of one or more other features.

Certain embodiments are described with reference to illustrations having specific shapes, but these shapes may vary as a result of, for example, manufacturing techniques and/or tolerances. Accordingly, the described embodiments should not be construed as limited to the particular shapes illustrated herein but are to include deviations in shapes that result, for example, from manufacturing. For example, an implanted region illustrated as a rectangle will typically have rounded or curved features and/or a gradient of implant concentration at its edges rather than a binary change from implanted to non-implanted region. Similarly, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art. Terms such as those defined in commonly used dictionaries should be interpreted as having a meaning that is consistent with their meaning in the context of the relevant art and will not be interpreted in an idealized or overly formal sense unless expressly so defined herein.

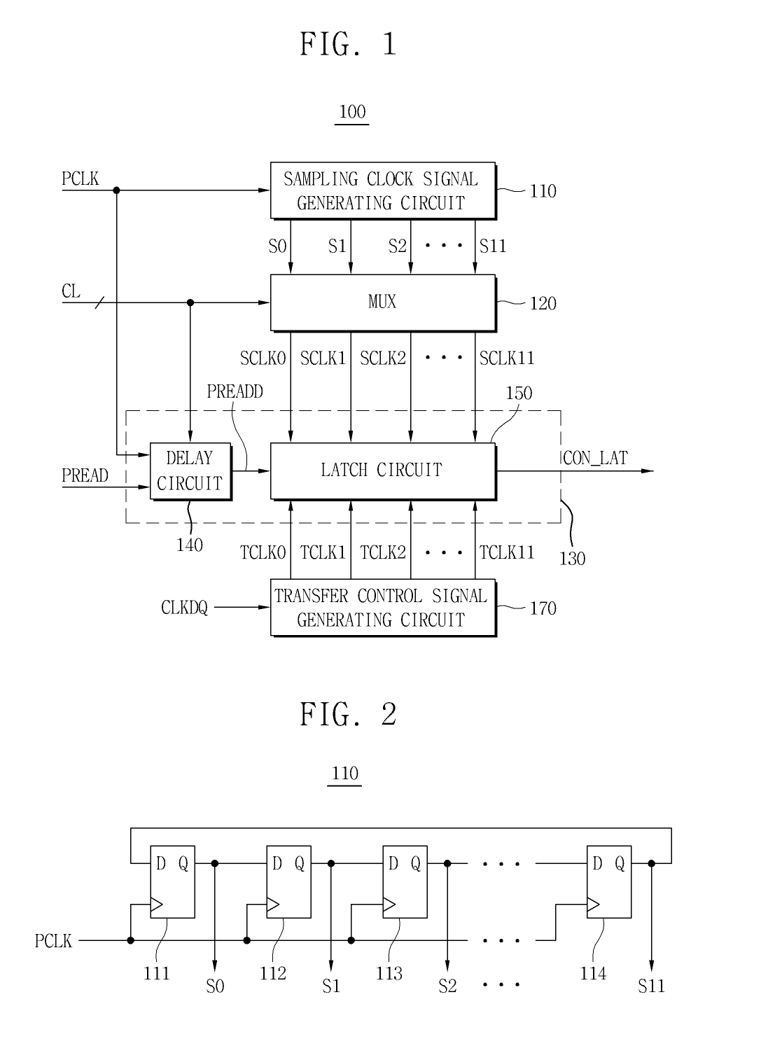

FIG. 1 is a block diagram of a latency control circuit 100 according to an embodiment of the inventive concept.

Referring to FIG. 1, latency control circuit 100 comprises a sampling clock signal generating circuit 110, a multiplexer 120, a latency control signal generating circuit 130, and a transfer control signal generating circuit 170.

Sampling clock signal generating circuit 110 generates a plurality of sampling clock signals S0 to S11 having different phases from each other based on an internal clock signal PCLK.

Multiplexer 120 performs multiplexing on sampling clock signals S0 to S11 in response to a column address strobe (CAS) latency signal CL to generate a plurality of sampling control signals SCLK0 to SCLK11.

Latency control signal generating circuit 130 delays a read information signal PREAD in response to CAS latency signal CL and internal clock signal PCLK to generate a delayed read information signal PREADD, and generates a latency control signal CON_LAT based on delayed read information signal PREADD in response to sampling control signals SCLK0 to SCLK11 and transfer control signals TCLK0 to TCLK11.

Latency control signal generating circuit 130 comprises a delay circuit 140 and a latch circuit 150. Delay circuit 140 delays read information signal PREAD in response to CAS latency signal CL and internal clock signal PCLK to generate delayed read information signal PREADD. Latch circuit 150 latches delayed read information signal PREADD in response to sampling control signals SCLK0 to SCLK11 and transfer control signals TCLK0 to TCLK11 to generate latency control signal CON_LAT.

Transfer control signal generating circuit 170 generates transfer control signals TCLK0 to TCLK11 with different phases from each other based on an output clock signal CLKDQ.

Internal clock signal PCLK is typically generated by a delay-locked-loop (DLL) circuit in a semiconductor memory device. Sampling clock signals S0 to S11 have a phase difference of an integer multiple of a clock cycle (tCC) of internal clock signal PCLK. Sampling clock signal generating circuit 110 comprises a shift register that is synchronized with internal clock signal PCLK, and may generate sampling clock signals S0 to S11 that are sequentially enabled with a delay time of clock cycle tCC.

Although FIG. 1 shows latency control circuit 100 with twelve sampling control signals SCLK0 to SCLK11 and twelve transfer control signals TCLK0 to TCLK11, latency control circuit 100 may use an arbitrary number of sampling control signals and transfer control signals.

FIG. 2 is a circuit diagram of a sampling clock signal generating circuit 110 in latency control circuit 100 of FIG. 1 according to an embodiment of the inventive concept.

Referring to FIG. 2, sampling clock signal generating circuit 110 comprises flip-flops 111 to 114 connected in a cascaded form and operating in response to internal clock signal PCLK. Sampling clock signal generating circuit 110 has a structure of a shift register with an input terminal of flip-flop 111 electrically connected with an output terminal of flip-flop 114. Sampling clock signals S0 to S11 are sequentially enabled with a delay time of clock cycle tCC. Although FIG. 2 shows sampling clock signal generating circuit 110 with D-type flip-flops, sampling clock signal generating circuit 110 may comprise other types of flip-flops.

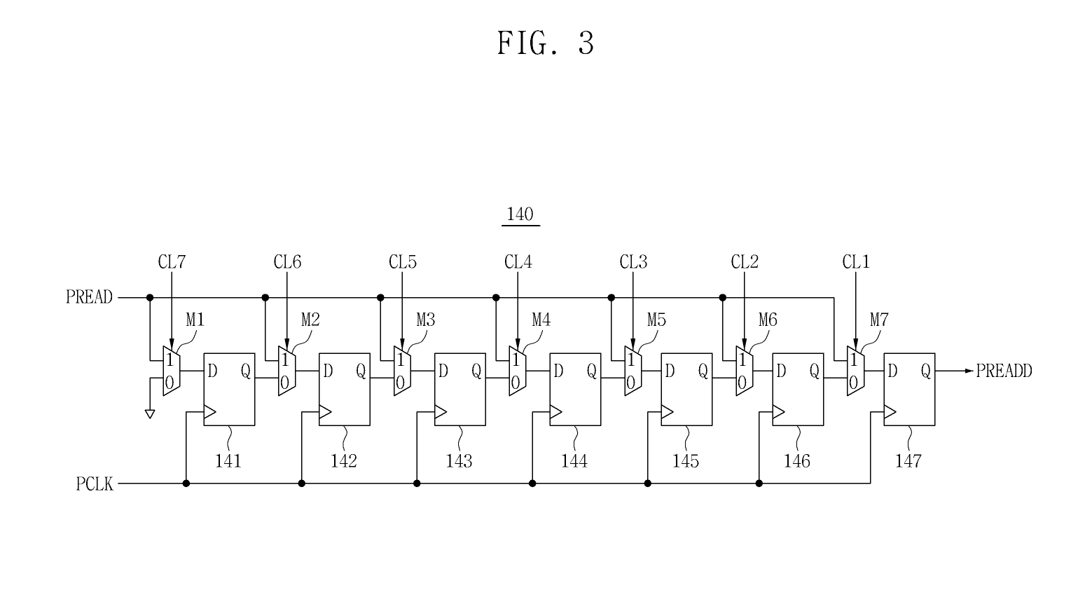

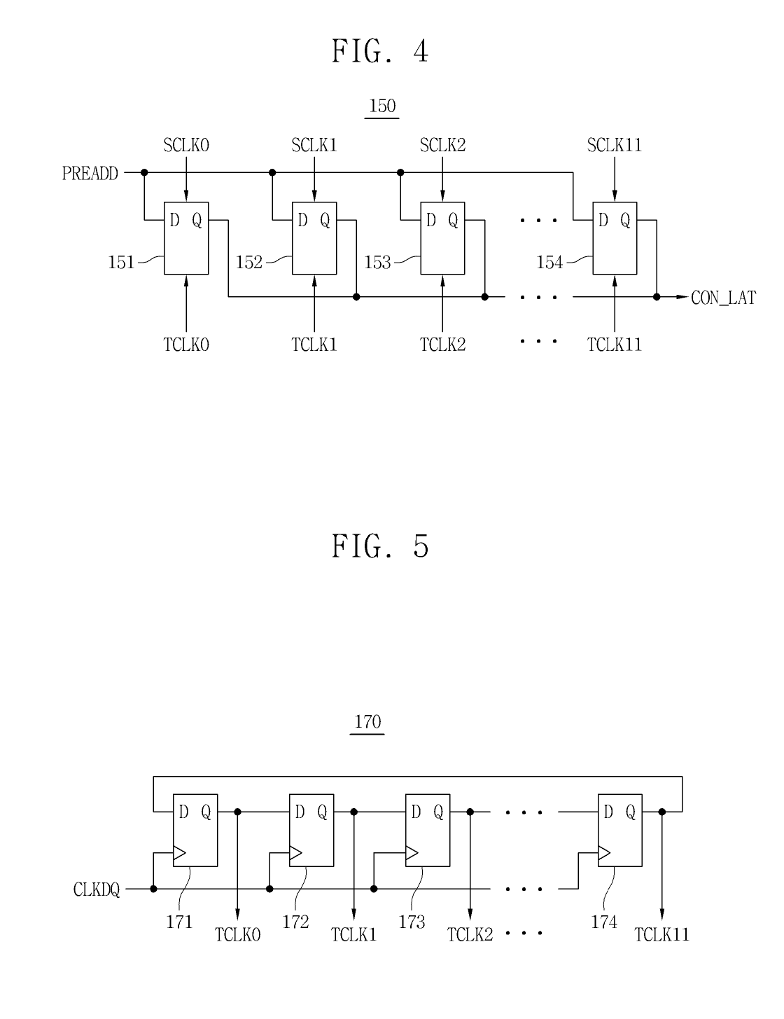

FIG. 3 is a circuit diagram of delay circuit 140 in latency control circuit 100 of FIG. 1 according to an embodiment of the inventive concept. Delay circuit 140 shown in FIG. 3 has a structure of a counter in which a delay time is adjusted according to a value of CAS latency signal CL.

Referring to FIG. 3, delay circuit 140 comprises a first multiplexer M1, a first flip-flop 141, a second multiplexer M2, a second flip-flop 142, a third multiplexer M3, a third flip-flop 143, a fourth multiplexer M4, a fourth flip-flop 144, a fifth multiplexer M5, a fifth flip-flop 145, a sixth multiplexer M6, a sixth flip-flop 146, a seventh multiplexer M7, and a seventh flip-flop 147.

First multiplexer M1 selects one of read information signal PREAD and a ground voltage in response to a seventh bit CL7 of the CAS latency signal, and outputs the selected signal. First flip-flop 141 latches an output signal of first multiplexer M1 in response to internal clock signal PCLK.

Second multiplexer M2 selects one of read information signal PREAD and an output signal of first flip-flop 141 in response to a sixth bit CL6 of the CAS latency signal, and outputs the selected signal. Second flip-flop 142 latches an output signal of second multiplexer M2 in response to internal clock signal PCLK.

Third multiplexer M3 selects one of read information signal PREAD and an output signal of second flip-flop 142 in response to a fifth bit CL5 of the CAS latency signal, and outputs the selected signal. Third flip-flop 143 latches an output signal of third multiplexer M3 in response to internal clock signal PCLK.

Fourth multiplexer M4 selects one of read information signal PREAD and an output signal of third flip-flop 143 in response to a fourth bit CL4 of the CAS latency signal, and outputs the selected signal. Fourth flip-flop 144 latches an output signal of fourth multiplexer M4 in response to internal clock signal PCLK.

Fifth multiplexer M5 selects one of read information signal PREAD and an output signal of fourth flip-flop 144 in response to a third bit CL3 of the CAS latency signal, and outputs the selected signal. Fifth flip-flop 145 latches an output signal of fifth multiplexer M5 in response to internal clock signal PCLK.

Sixth multiplexer M6 selects one of read information signal PREAD and an output signal of fifth flip-flop 145 in response to a second bit CL2 of the CAS latency signal, and outputs the selected signal. Sixth flip-flop 146 latches an output signal of sixth multiplexer M6 in response to internal clock signal PCLK.

Seventh multiplexer M7 selects one of read information signal PREAD and an output signal of sixth flip-flop 146 in response to a first bit CL1 of the CAS latency signal, and outputs the selected signal. Seventh flip-flop 147 latches an output signal of seventh multiplexer M7 in response to internal clock signal PCLK.

To illustrate the operation of delay circuit 140, suppose seventh bit CL7 has a value of 1 and first to sixth bits CL1 to CL6 have a value of 0. Under these conditions, delay circuit 140 delays read information signal PREAD by seven clock cycles of the internal clock signal (PCLK) to generate delayed read information signal PREADD. Where sixth and seventh bits CL6 and CL7 have a value of 1 and first to fifth bits CL1 to CL5 have a value of 0, delay circuit 140 delays read information signal PREAD by six clock cycles of the internal clock signal (PCLK) to generate delayed read information signal PREADD. Where second to seventh bits CL2 to CL7 have a value of 1 and first bit CL1 has a value of 0, delay circuit 140 delays read information signal PREAD by two clock cycles of the internal clock signal (PCLK) to generate delayed read information signal PREADD. Where all of first to seventh bits CL1 to CL7 have a value of 1, delay circuit 140 delays read information signal PREAD by one clock cycle of internal clock signal (PCLK) to generate delayed read information signal PREADD.

Where seventh bit CL7 of CAS latency signal CL has a value of 1 and first to sixth bits CL1 to CL6 of the CAS latency signal have a value of 0, delay circuit 140 may have the longest delay time, and where all of first to seventh bits CL1 to CL7 of CAS latency signal CL have a value of 1, delay circuit 140 may have the shortest delay time.

Where latency control circuit 100 of FIG. 1 comprises delay circuit 140 of FIG. 3, it allows a semiconductor memory device comprising latency control circuit 100 to delay read information signal PREAD to be suitable for the CAS latency of the semiconductor memory device, and may generate a latency control signal CON_LAT based on delayed read information signal PREADD in response to sampling control signals SCLK0 to SCLK11 and transfer control signals TCLK0 to TCLK11.

In general, a semiconductor memory device comprising latency control circuit 100 may have a circuit block such as a multiplexer having a relatively simple structure for multiplexing the sampling clock signal, which may allow the semiconductor memory device to be implemented with a small chip size, high-speed operation and latency of high value.

FIG. 4 is a circuit diagram of a latch circuit 150 in latency control circuit 100 of FIG. 1 according to an embodiment of the inventive concept.

Referring to FIG. 4, latch circuit 150 comprises flip-flops 151 to 154. First flip-flop 151 latches delayed read information signal PREADD in response to first sampling control signal SCLK0 and first transfer control signal TCLK0. Second flip-flop 152 latches delayed read information signal PREADD in response to second sampling control signal SCLK1 and second transfer control signal TCLK1. Third flip-flop 153 latches delayed read information signal PREADD in response to third sampling control signal SCLK2 and a third transfer control signal TCLK2. Fourth flip-flop 153 latches delayed read information signal PREADD in response to twelfth sampling control signal SCLK11 and twelfth transfer control signal TCLK11 to generate latency control signal CON_LAT. The output terminals of the flip-flops 151 to 154 in latch circuit 150 are electrically connected to each other.

FIG. 5 is a circuit diagram of a transfer control signal generating circuit 170 in latency control circuit 100 of FIG. 1 according to an embodiment of the inventive concept.

Referring to FIG. 5, transfer control signal generating circuit 170 comprises flip-flops 171 to 174 connected in a cascaded form and operating in response to output clock signal CLKDQ. Transfer control signal generating circuit 170 has a structure of a shift register with an input terminal of flip-flop 171 electrically connected with an output terminal of flip-flop 174. Transfer control signals TCLK0 to TCLK 11 are synchronized with output clock signal CLKDQ, and they are sequentially enabled with a delay time of clock cycle tCC. Although FIG. 5 shows transfer control signal generating circuit 170 with D-type flip-flops, transfer control signal generating circuit 170 may comprise other types of flip-flops.

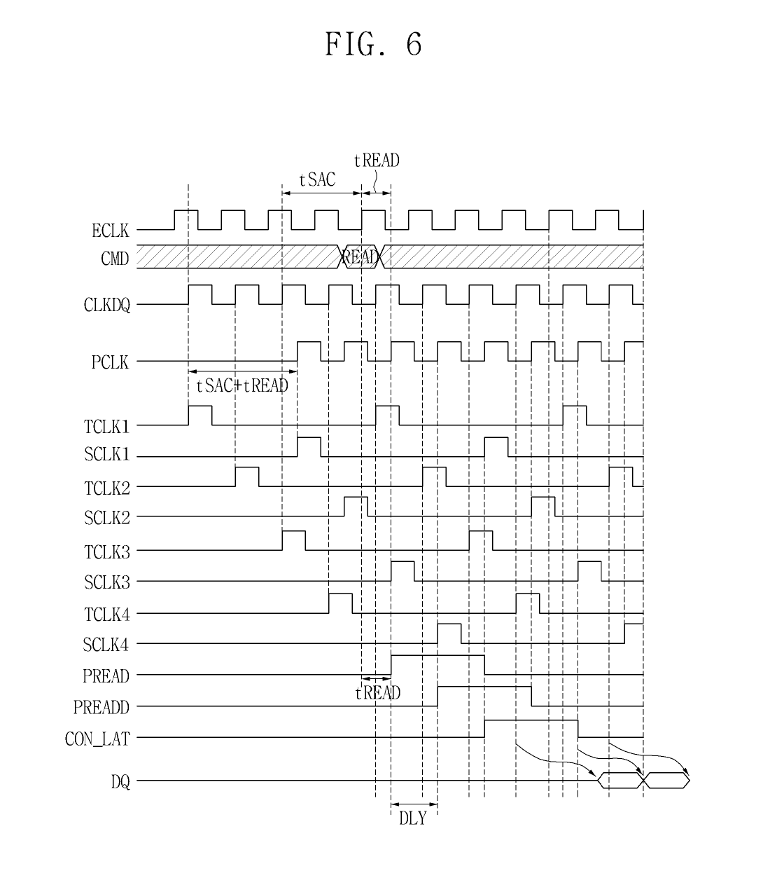

FIG. 6 is a timing diagram illustrating an operation of latency control circuit 100 of FIG. 1 according to an embodiment of the inventive concept. In FIG. 6, ECLK denotes an external clock signal, CMD denotes a read command (READ), CLKDQ denotes an output clock signal, PCLK denotes an internal clock signal, SCLK1 to SCLK4 denote sampling control signals, TCLK1 to TCLK4 denote transfer control signals, PREAD denotes a read information signal, PREADD denotes a delayed read information signal, CON_LAT denotes a latency control signal, and DQ denotes output data, respectively. Further, in FIG. 6, tREAD denotes a time between a rising edge of the ECLK and a rising edge of the PREAD when read command CMD is generated, and tSAC denotes a time between pulses of CLKDQ and pulses of ECLK.

Referring to FIG. 6, latency control circuit 100 delays read information signal PREAD by a first delay time DLY to generate delayed read information signal PREADD, and generates latency control signal CON_LAT based on delayed read information signal PREADD. The use of latency control circuit 100 allows the size of a circuit for generating sampling control signals comprising a multiplexer to be decreased.

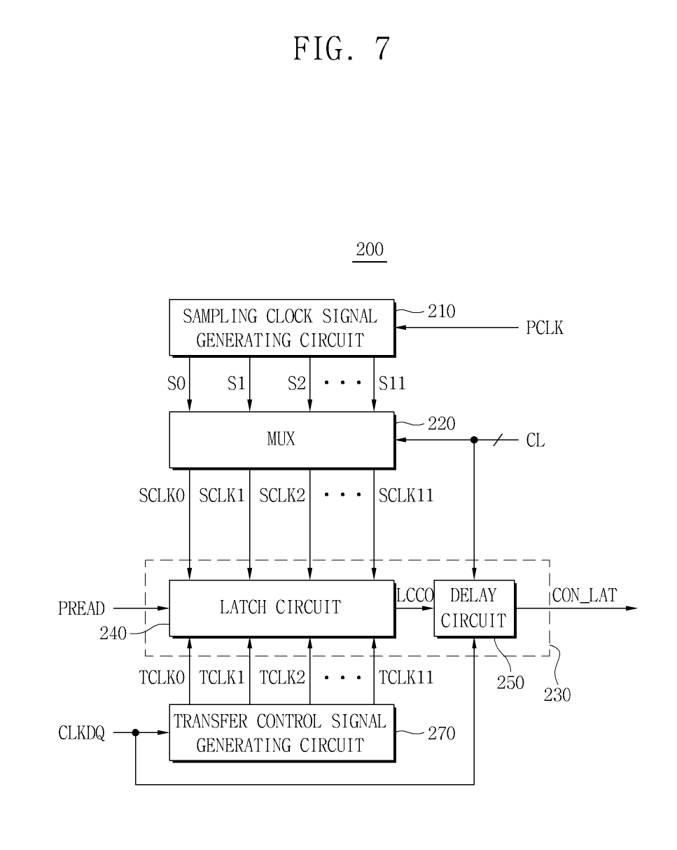

FIG. 7 is a block diagram of a latency control circuit 200 according to another embodiment of the inventive concept.

Referring to FIG. 7, latency control circuit 200 comprises a sampling clock signal generating circuit 210, a multiplexer 220, a latency control signal generating circuit 230, and a transfer control signal generating circuit 270.

Sampling clock signal generating circuit 210 generates a plurality of sampling clock signals S0 to S11 having different phases from each other based on an internal clock signal PCLK.

Multiplexer 220 performs multiplexing on sampling clock signals S0 to S11 in response to a CAS latency signal CL to generate a plurality of sampling control signals SCLK0 to SCLK11.

Latency control signal generating circuit 230 latches a read information signal PREAD in response to sampling control signals SCLK0 to SCLK11 and transfers control signals TCLK0 to TCLK11 to generate a first signal LCCO. Latency control signal generating circuit 230 delays first signal LCCO in response to CAS latency signal CL and output clock signal CLKDQ to generate a latency control signal CON_LAT.

Latency control signal generating circuit 230 comprises a latch circuit 240 and a delay circuit 250.

Latch circuit 240 latches read information signal PREAD in response to sampling control signals SCLK0 to SCLK11 and transfer control signals TCLK0 to TCLK11 to generate first signal LCCO. Delay circuit 250 delays first signal LCCO in response to CAS latency signal CL and output clock signal CLKDQ to generate latency control signal CON_LAT.

Internal clock signal PCLK typically comprises a clock signal generated by a delay-locked-loop (DLL) circuit in a semiconductor memory device. Sampling clock signals S0 to S11 may have a phase difference of an integer multiple of a clock cycle (tCC) of internal clock signal PCLK. Sampling clock signal generating circuit 210 comprises a shift register that is synchronized with internal clock signal PCLK, and it generates sampling clock signals S0 to S11 that are sequentially enabled with a delay time of clock cycle tCC.

Transfer control signal generating circuit 270 generates a plurality of transfer control signals TCLK0 to TCLK11 having different phases from each other based on an output clock signal CLKDQ.

Although FIG. 7 shows latency control circuit 200 using twelve sampling control signals SCLK0 to SCLK11 and twelve transfer control signals TCLK0 to TCLK11, latency control circuit 200 may use an arbitrary number of sampling control signals and transfer control signals.

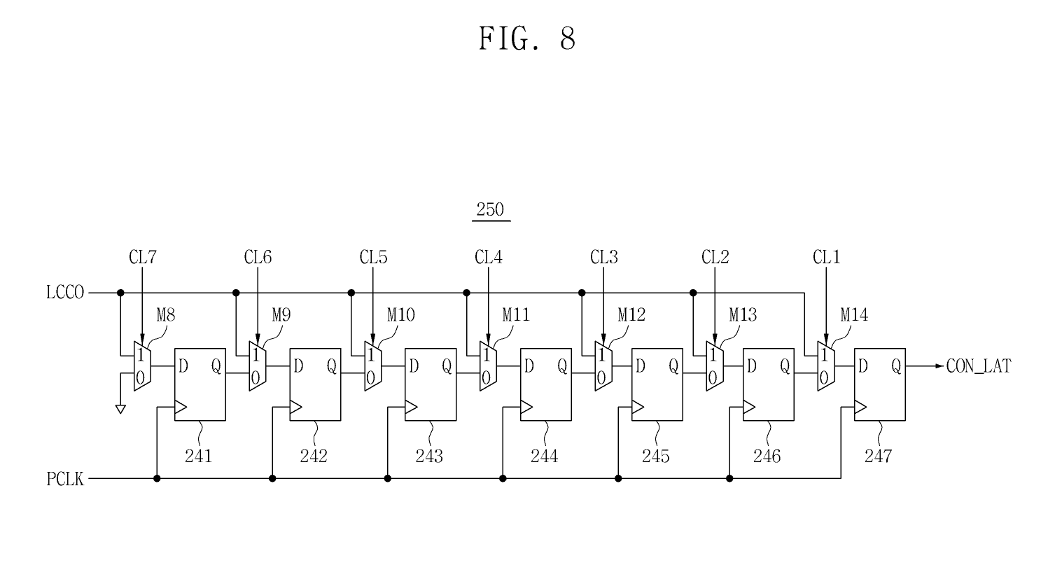

FIG. 8 is a circuit diagram of delay circuit 250 in latency control circuit 200 of FIG. 7 according to an embodiment of the inventive concept.

Referring to FIG. 8, delay circuit 250 comprises a first multiplexer M8, a first flip-flop 241, a second multiplexer M9, a second flip-flop 242, a third multiplexer M10, a third flip-flop 243, a fourth multiplexer M11, a fourth flip-flop 244, a fifth multiplexer M12, a fifth flip-flop 245, a sixth multiplexer M13, a sixth flip-flop 246, a seventh multiplexer M14, and a seventh flip-flop 247.

First multiplexer M8 selects one of first signal LCCO and a ground voltage in response to a seventh bit CL7 of CAS latency signal CL, and outputs the selected signal. First flip-flop 241 latches an output signal of first multiplexer M8 in response to internal clock signal PCLK.

Second multiplexer M9 selects one of first signal LCCO and an output signal of first flip-flop 241 in response to a sixth bit CL6 of the CAS latency signal, and outputs the selected signal. Second flip-flop 242 latches an output signal of second multiplexer M9 in response to internal clock signal PCLK.

Third multiplexer M10 selects one of first signal LCCO and an output signal of second flip-flop 242 in response to a fifth bit CL5 of the CAS latency signal, and outputs the selected signal. Third flip-flop 243 latches an output signal of third multiplexer M10 in response to internal clock signal PCLK.

Fourth multiplexer M11 selects one of first signal LCCO and an output signal of third flip-flop 243 in response to a fourth bit CL4 of the CAS latency signal, and outputs the selected signal. Fourth flip-flop 244 latches an output signal of fourth multiplexer M11 in response to internal clock signal PCLK.

Fifth multiplexer M12 selects one of first signal LCCO and an output signal of fourth flip-flop 244 in response to a third bit CL3 of the CAS latency signal, and outputs the selected signal. Fifth flip-flop 245 latches an output signal of fifth multiplexer M12 in response to internal clock signal PCLK.

Sixth multiplexer M13 selects one of first signal LCCO and an output signal of fifth flip-flop 245 in response to a second bit CL2 of the CAS latency signal, and outputs the selected signal. Sixth flip-flop 246 latches an output signal of sixth multiplexer M13 in response to internal clock signal PCLK.

Seventh multiplexer M14 selects one of first signal LCCO and an output signal of sixth flip-flop 246 in response to a first bit CL1 of the CAS latency signal, and outputs the selected signal. Seventh flip-flop 247 latches an output signal of seventh multiplexer M14 in response to internal clock signal PCLK to generate latency control signal CON_LAT.

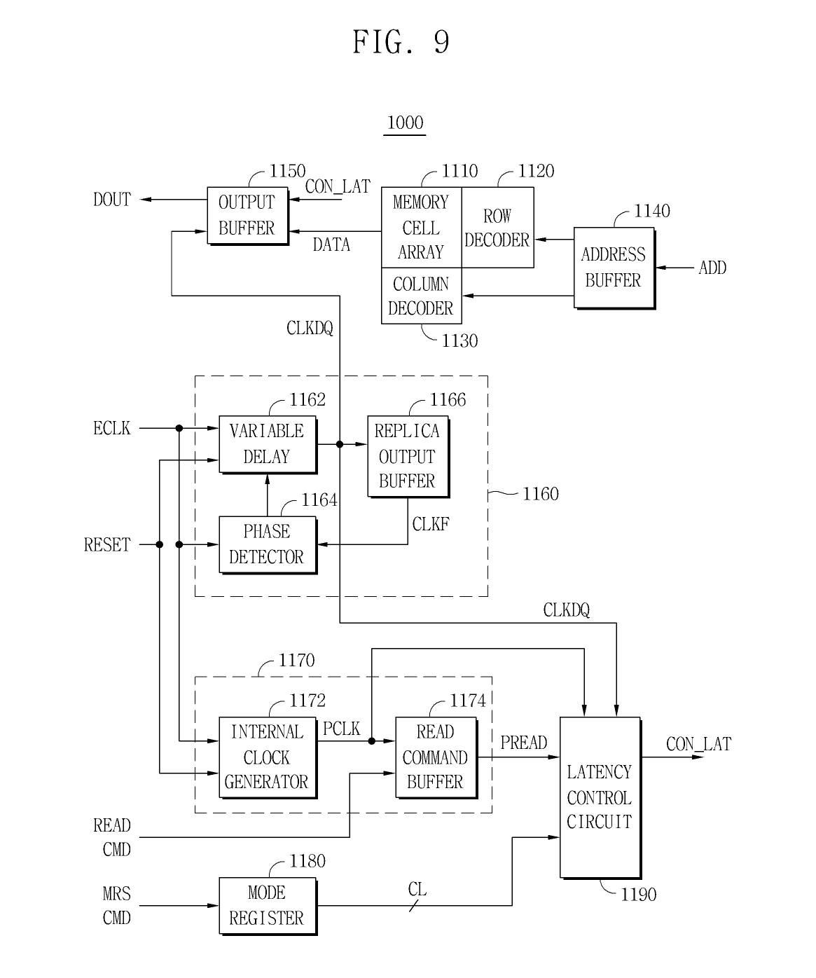

FIG. 9 is a block diagram of a semiconductor memory device 1000 comprising a latency control circuit according to an embodiment of the inventive concept.

Referring to FIG. 9, semiconductor memory device 1000 comprises a memory cell array 1110, a row decoder 1120, a column decoder 1130, an address buffer 1140, an output buffer 1150, a clock synchronizing circuit 1160, a read command circuit 1170, a mode register 1180, and a latency control circuit 1190.

Clock synchronizing circuit 1160 is a delay-locked-loop circuit and comprises a variable delay 1162, a phase detector 1164 and a replica output buffer 1166. Read command circuit 1170 comprises an internal clock generator 1172 and a read command buffer 1174. Variable delay 1162 can be reset by a reset signal RESET.

Data can be written in memory cell array 1110 or read from memory cell array 1110. Where read command READ CMD is applied to semiconductor memory device 1000, the data is read out of memory cell array 1110 according to an address ADD. Address buffer 1140 temporarily stores address ADD. Row decoder 1120 receives address ADD from address buffer 1140 and decodes address ADD to generate a row address. Column decoder 1130 receives address ADD from address buffer 1140 and decodes address ADD to generate a column address. Memory cell array 1110 outputs data from the memory cell defined by the row address and the column address. Output buffer 1150 receives data output from memory cell array 1110, and outputs the received data in response to a latency control signal CON_LAT output from latency control circuit 1190 and an output clock signal CLKDQ.

Clock synchronizing circuit 1160 generates output clock signal CLKDQ in response to external clock signal ECLK. External clock signal ECLK may be used as a reference clock signal for most commands in semiconductor memory device 1000. That is, most of the commands may be synchronized with external clock signal ECLK and applied to semiconductor memory device 1000.

Clock synchronizing circuit 1160 generates output clock signal CLKDQ that leads in phase compared with external clock signal ECLK. Output clock signal CLKDQ has the same frequency as external clock signal ECLK, but pulses of output clock signal CLKDQ lead in phase by a data output time tSAC compared with pulses of external clock signal ECLK. Therefore, clock synchronizing circuit 1160 synchronizes data output from output buffer 1150 with external clock signal ECLK.

Read command circuit 1170 generates internal clock signal PCLK and read information signal PREAD based on read command READ CMD and external clock signal ECLK. Internal clock generator 1172 generates internal clock signal PCLK based on external clock signal ECLK, and read command buffer 1174 generates read information signal PREAD based on read command READ CMD. Internal clock generator 1172 can be reset by reset signal RESET. Latency control circuit 1190 receives CAS latency CL, and generates latency control signal CON_LAT with which output buffer 1150 outputs data at a designated time. Output buffer 1150 outputs data in response to output clock signal CLKDQ where latency control signal CON_LAT is enabled.

Latency control circuit 1190 typically has a structure of a latency control circuit such as that illustrated in FIG. 1 or 7. Latency control circuit 1190 delays a read information signal according to a CAS latency signal and an internal clock signal to generate a delayed read information signal, and generates a latency control signal based on the delayed read information signal in response to sampling control signals and transfer control signals. Multiplexers in the latency control circuit may have a relatively simple structure, and the latency control circuit can potentially have a relatively small chip size, high-speed operation, and high latency value.

Semiconductor memory device 1000 of FIG. 9 may comprise a volatile memory chip such as a dynamic random access memory (DRAM) and a static random access memory (SRAM), a non-volatile memory chip such as a flash memory, a phase change memory, a magnetic random access memory (MRAM), or a resistive random access memory (RRAM), or a combination of thereof.

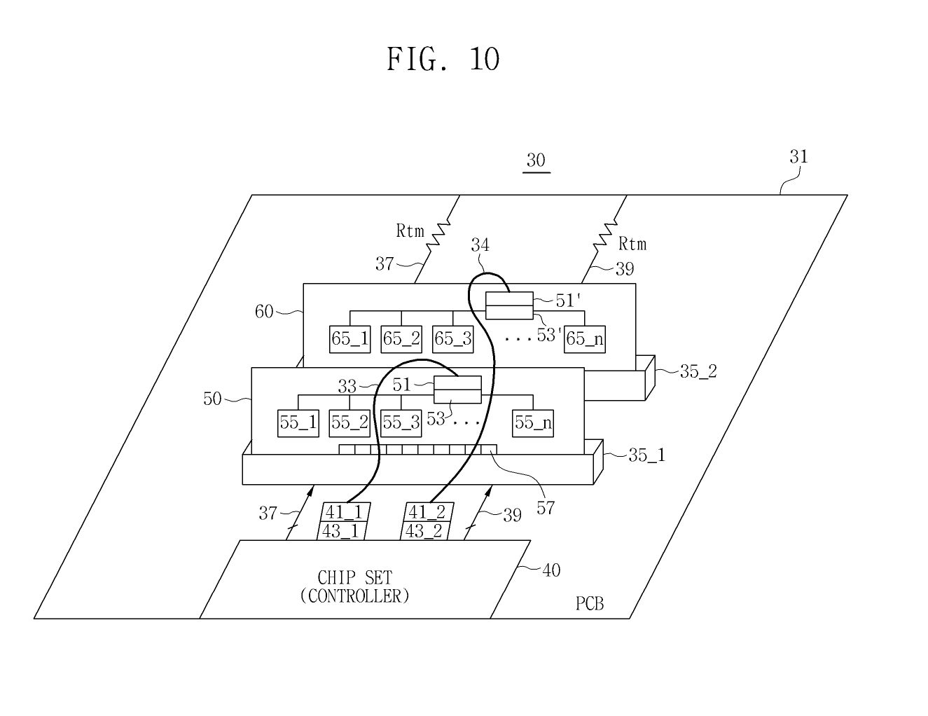

FIG. 10 is a block diagram of a memory system 30 comprising a semiconductor memory device according to an embodiment of the inventive concept.

Referring to FIG. 10, memory system 30 comprises a motherboard 31, a chip set (or a controller) 40, slots 35_1 and 35_2, memory modules 50 and 60, and transmission lines 33 and 34. Buses 37 and 39 connect chip set 40 with slots 35_1 and 35_2. A terminal resistor Rtm may terminate each of buses 37 and 39 on a printed circuit board (PCB) of motherboard 31.

For convenience, FIG. 10 shows only two slots 35_1 and 35_2 and two memory modules 50 and 60, but memory system 30 may comprise an arbitrary number of slots and memory modules.

Chip set 40 is mounted on a PCB of motherboard 31, and controls the operation of memory system 30. Chip set 40 comprises connectors 41_1 and 41_2 and converters 43_1 and 43_2.

Converter 43_1 receives parallel data generated by chip set 40, converts the parallel data to serial data, and outputs the serial data to transmission line 33 via connector 41_1. Converter 43_1 receives serial data via transmission line 33, and converts the serial data to parallel data and outputs the parallel data to chip set 40.

Converter 43_2 receives parallel data generated by chip set 40, converts the parallel data to serial data, and outputs the serial data to transmission line 34 via connector 41_2. Converter 43_2 receives serial data via transmission line 34, and converts the serial data to parallel data and outputs the parallel data to chip set 40. Transmission lines 33 and 34 in memory system 30 may be a plurality of optical fibers.

Memory module 50 comprises a plurality of memory devices 55_1 to 55_n, a first connector 57, a second connector 51, and a converter 53. Memory module 60 comprises a plurality of memory devices 65_1 to 65_n, a first connector 57′, a second connector 51′, and a converter 53′.

First connector 57 transfers low-speed signals received from chip set 40 to memory devices 55_1 to 55_n, and second connector 51 is connected to transmission line 33 for transferring high-speed signals.

Converter 53 receives serial data via second connector 51, converts the serial data to parallel data, and outputs the parallel data to memory devices 55_1 to 55_n. Converter 53 also receives parallel data from memory devices 55_1 to 55_n, converts the parallel data to serial data, and outputs the serial data to second connector 51.

Memory devices 55_1 to 55_n and 65_1 to 65_n can be implemented by a semiconductor memory device such as that illustrated in FIG. 9. Accordingly, they may comprise features such as those described above.

Additionally, memory devices 55_1 to 55_n and 65_1 to 65_n can be volatile memory chips such as a dynamic random access memory (DRAM) and a static random access memory (SRAM), a non-volatile memory chip such as a flash memory, a phase change memory, a magnetic random access memory (MRAM), or a resistive random access memory (RRAM), or a combination of thereof.

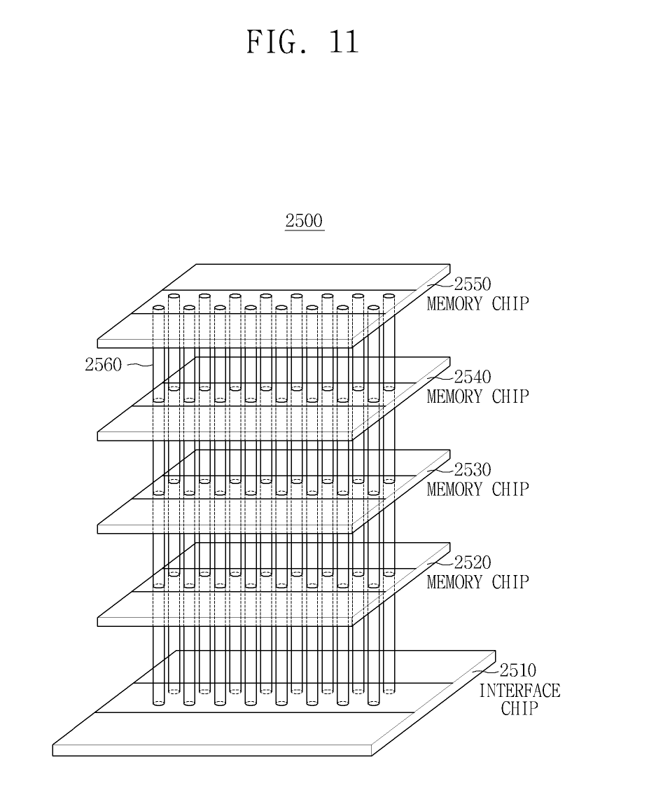

FIG. 11 is a diagram of a stacked semiconductor device 2500 comprising a semiconductor memory device comprising a latency control circuit according to an embodiment of the inventive concept.

Referring to FIG. 11, stacked semiconductor device 2500 comprises an interface chip 2510, and memory chips 2520, 2530, 2540 and 2550 which are electrically connected by through-silicon vias 2560. Although FIG. 11 shows through-silicon vias 2560 disposed in two rows, stacked semiconductor device 2500 may comprise any number of through-silicon vias.

Memory chips 2520, 2530, 2540 and 2550 in stacked semiconductor device 2500 may comprise a latency control circuit as described above in relation to FIG. 1 or 7, for instance. Interface chip 2510 provides an interface between memory chips 2520, 2530, 2540 and 2550 and external devices.

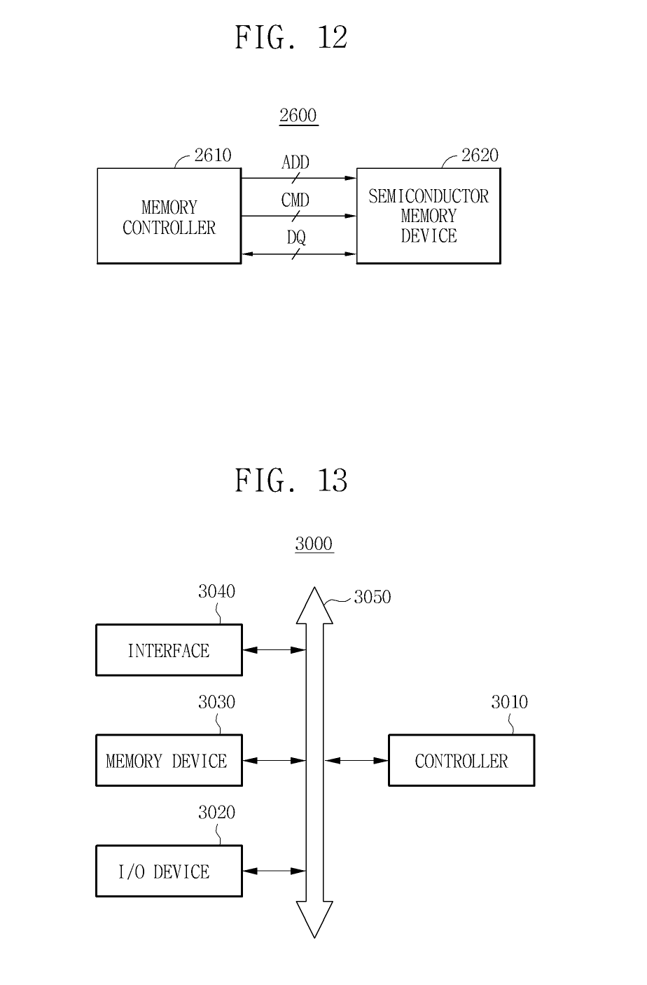

FIG. 12 is a block diagram of a memory system 2600 comprising a semiconductor memory device according to an embodiment of the inventive concept.

Referring to FIG. 12, memory system 2600 comprises a memory controller 2610 and a semiconductor memory device 2620.

Memory controller 2610 generates address signals ADD and command signals CMD, and it provides address signals ADD and command signals CMD to semiconductor memory device 2620 through buses. Data DQ is transmitted from memory controller 2610 to semiconductor memory device 2620 through the buses, or transmitted from stacked semiconductor memory device 2620 to memory controller 2610 through the buses.

Semiconductor memory device 2620 may comprise the latency control circuit such as that illustrated in FIG. 1 or 7, for instance.

FIG. 13 is a block diagram of an electronic system 3000 comprising a semiconductor memory device comprising an internal voltage generating circuit according to an embodiment of the inventive concept.

Referring to FIG. 15, electronic system 3000 comprises a controller 3010, an input and output device 3020, a memory device 3030, an interface 3040, and a bus 3050. Memory device 3030 can be a semiconductor memory device comprising a latency control circuit such as that illustrated in FIG. 1 or 7, for instance. Bus 3050 may function to provide a path in that data is mutually moved among controller 3010, input and output device 3020, memory device 3030, and interface 3040.

Controller 3010 may comprise, for instance, any logic device capable of performing functions of at least one of a microprocessor, a digital signal processer, and a microcontroller, or functions similar to those. Input and output device 3020 may comprise, for instance, a key pad, key board, or a display device. Memory device 3030 may function to store data and/or instructions performed by controller 3010.

Memory device 3030 typically comprises a volatile memory chip such as a dynamic random access memory (DRAM) and a static random access memory (SRAM), a non-volatile memory chip such as a flash memory, a phase change memory, a magnetic random access memory (MRAM), or a resistive random access memory (RRAM), or a combination of thereof. Memory device 3030 may be the semiconductor memory device comprising the latency control circuit according to an embodiment of the inventive concept.

Interface 3040 may function to transmit/receive data to/from a communication network. Interface 3040 can comprise an antenna, wired or wireless transceivers or the like, to transmit and receive data by wires or wirelessly. In addition, interface 3040 can comprise optical fibers to transmit and receive data through the optical fibers. Electronic system 3000 may be further provided with an application chipset, a camera image processor, and an input and output device.

Electronic system 3000 may be implemented as a mobile system, personal computer, an industrial computer, or a logic system that can perform various functions, for instance. As examples, the mobile system may be any one of a personal digital assistant (PDA), a portable computer, a web tablet, a mobile phone, a wireless phone, a laptop computer, a memory card, a digital music system, and an information transmitting/receiving system. Where electronic system 3000 is an apparatus that can perform wireless communication, electronic system 3000 may be used in a communication system such as a Code Division multiple Access (CDMA), a Global System for Mobile communication (GSM), a North American Digital Cellular (NADC), an Enhanced-Time Division Multiple Access (E-TDMA), a Wideband Code Division Multiple Access (WCDMA), or a CDMA 2000.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the inventive concept. Accordingly, all such modifications are intended to be included within the scope of the inventive concept as defined in the claims.

What is claimed is:

1. A latency control circuit, comprising:
a sampling clock signal generating circuit configured to generate a plurality of sampling clock signals having different phases from each other based on an internal clock signal;
a multiplexer configured to multiplex the sampling clock signals in response to a column address strobe (CAS) latency signal to generate a plurality of sampling control signals;
a transfer control signal generating circuit configured to generate a plurality of transfer control signals having different phases from each other based on an output clock signal; and
a latency control signal generating circuit configured to delay a read information signal in response to the CAS latency signal and the internal clock signal to generate a delayed read information signal, and further configured to generate a latency control signal based on the delayed read information signal in response to the sampling control signals and the transfer control signals.

2. The latency control circuit of claim 1, wherein the sampling clock signals are configured to have a phase difference of an integer multiple of a clock cycle of the internal clock signal.

3. The latency control circuit of claim 2, wherein the sampling clock signal generating circuit comprises:
a shift register synchronized with the internal clock signal and configured to generate the sampling clock signals that are sequentially enabled with a delay time of the clock cycle.

4. The latency control circuit of claim 1, wherein the latency control signal generating circuit comprises:
a delay circuit configured to delay the read information signal in response to the CAS latency signal and the internal clock signal to generate the delayed read information signal; and
a latch circuit configured to latch the delayed read information signal in response to the sampling control signals and the transfer control signals to generate the latency control signal.

5. The latency control circuit of claim 4, wherein the delay circuit comprises a plurality of unit circuits connected in a cascaded form, each of the unit circuits comprising:
a multiplexer configured to select one of the read information signal and a flip-flop output signal in response to each bit of the CAS latency signal; and
a flip-flop configured to latch an output signal of the multiplexer in response to the internal clock signal.

6. The latency control circuit of claim 5, wherein, among the unit circuits in the delay circuit, a multiplexer connected to an input terminal of the delay circuit is configured to select one of the read information signal and a ground voltage in response to one bit of the CAS latency signal, and output the selected signal.

7. The latency control circuit of claim 4, wherein the delay circuit comprises a counter in which a delay time is adjusted according to a value of the CAS latency signal.

8. The latency control circuit of claim 4, wherein the delay circuit comprises:
a first multiplexer configured to select one of the read information signal and a ground voltage in response to a seventh bit of the CAS latency signal, and output the selected signal;
a first flip-flop configured to latch an output signal of the first multiplexer in response to the internal clock signal;
a second multiplexer configured to select one of the read information signal and an output signal of the first flip-flop in response to a sixth bit of the CAS latency signal, and output the selected signal;
a second flip-flop configured to latch an output signal of the second multiplexer in response to the internal clock signal;
a third multiplexer configured to select one of the read information signal and an output signal of the second flip-flop in response to a fifth bit of the CAS latency signal, and output the selected signal;
a third flip-flop configured to latch an output signal of the third multiplexer in response to the internal clock signal;
a fourth multiplexer configured to select one of the read information signal and an output signal of the third flip-flop in response to a fourth bit of the CAS latency signal, and output the selected signal;
a fourth flip-flop configured to latch an output signal of the fourth multiplexer in response to the internal clock signal;
a fifth multiplexer configured to select one of the read information signal and an output signal of the fourth flip-flop in response to a third bit of the CAS latency signal, and output the selected signal;
a fifth flip-flop configured to latch an output signal of the fifth multiplexer in response to the internal clock signal;
a sixth multiplexer configured to select one of the read information signal and an output signal of the fifth flip-flop in response to a second bit of the CAS latency signal, and output the selected signal;
a sixth flip-flop configured to latch an output signal of the sixth multiplexer in response to the internal clock signal;
a seventh multiplexer configured to select one of the read information signal and an output signal of the sixth flip-flop in response to a first bit of the CAS latency signal, and output the selected signal; and
a seventh flip-flop configured to latch an output signal of the seventh multiplexer in response to the internal clock signal.

9. The latency control circuit of claim 8, wherein where the seventh bit of the CAS latency signal has a value of 1 and the sixth to first bits of the CAS latency signal have a value of 0, the delay circuit has a longest delay time.

10. The latency control circuit of claim 8, wherein where the seventh bit of the CAS latency signal has a value of 1 and the sixth to first bits of the CAS latency signal have a value of 0, the delay circuit is configured to delay the read information signal by seven clock cycles of the internal clock signal to generate the delayed read information signal.

11. The latency control circuit of claim 8, wherein where all of the seventh to first bits of the CAS latency signal have a value of 1, the delay circuit has a shortest delay time.

12. The latency control circuit of claim 8, wherein where all of the seventh to first bits of the CAS latency signal have a value of 1, the delay circuit is configured to delay the read information signal by one clock cycle of the internal clock signal to generate the delayed read information signal.

13. A semiconductor memory device comprising:
a memory cell array;
a latency control circuit configured to delay a read information signal in response to a column address strobe (CAS) latency signal and an internal clock signal to generate a delayed read information signal, and further configured to generate a latency control signal based on the delayed read information signal in response to a plurality of sampling control signals and a plurality of transfer control signals; and
an output buffer configured to receive data from the memory cell array and output the data received from the memory cell array in response to the latency control signal.

14. The semiconductor memory device of claim 13, wherein the latency control circuit comprises:
a sampling clock signal generating circuit configured to generate a plurality of sampling clock signals having different phases from each other based on the internal clock signal;
a multiplexer configured to perform multiplexing on the sampling clock signals in response to the CAS latency signal to generate the sampling control signals;
a transfer control signal generating circuit configured to generate the transfer control signals having different phases from each other based on an output clock signal; and
a latency control signal generating circuit configured to delay the read information signal in response to the CAS latency signal and the internal clock signal to generate the delayed read information signal, and configured to generate the latency control signal based on the delayed read information signal in response to the sampling control signals and transfer control signals.

15. The semiconductor memory device of claim 13, wherein the semiconductor memory device is a stacked memory device in which a plurality of chips communicates data and control signals by a through-silicon-via.

16. The semiconductor memory device of claim 14, wherein the sampling clock signals are configured to have a phase difference of an integer multiple of a clock cycle of the internal clock signal.

17. The semiconductor memory device of claim 13, wherein the memory cell array comprises a dynamic random access memory cell array or a static random access memory cell array.

18. A latency control circuit configured to delay a read information signal in response to a column address strobe (CAS) latency signal and an internal clock signal to generate a delayed read information signal, and further configured to generate a latency control signal based on the delayed read information signal in response to a plurality of sampling control signals and a plurality of transfer control signals.

19. The latency control circuit of claim 18, comprising:
a sampling clock signal generating circuit configured to generate a plurality of sampling clock signals having different phases from each other based on the internal clock signal;
a multiplexer configured to perform multiplexing on the sampling clock signals in response to the CAS latency signal to generate the sampling control signals;
a transfer control signal generating circuit configured to generate the transfer control signals having different phases from each other based on an output clock signal; and
a latency control signal generating circuit configured to delay the read information signal in response to the CAS latency signal and the internal clock signal to generate the delayed read information signal, and configured to generate the latency control signal based on the delayed read information signal in response to the sampling control signals and transfer control signals.

20. The latency control circuit of claim 19, wherein the sampling clock signals are configured to have a phase difference of an integer multiple of a clock cycle of the internal clock signal.
